(19) United States
(12) Patent Application Publication
(10) Pub. No.: US 2019/0111597 A1
(43) Pub. Date: Apr. 18, 2019

(54) MULTI-STEP MOLDING PROCESS FOR ELECTRONIC DEVICE CHASSIS

(71) Applicant: Facebook, Inc., Menlo Park, CA (US)

(72) Inventors: Rajesh Prasannavenkatesan, Menlo Park, CA (US); Rex Wenters Crossen, Piedmont, CA (US); Richard Heley, Los Altos, CA (US)

(21) Appl. No.: 15/787,566

(22) Filed: Oct. 18, 2017

(51) Int. Cl. B29C 45/14; B29C 45/16; B29C 70/88; B29C 70/72; H05K 3/28; H01L 21/48; H01L 21/56; H05K 5/00

(52) U.S. Cl. CPC B29C 45/14639; B29C 45/1671; B29C 45/1615; B29C 70/88; B29L 2031/3425; H05K 3/28; H01L 21/4803; H01L 21/565; H05K 5/0034; B29C 70/72

(57) ABSTRACT

An electronic device chassis is manufactured with a multi-step molding process. The process includes at least two separate injection molding steps. During the first step, an electronic component is placed in a first mold, and a first material is injected into the first mold to create a first chassis that surrounds part of the electronic component. In the second step, the first chassis is placed in a second mold, and a second material is injected into the second mold to create a second chassis that surrounds part of the first chassis. The second step can be performed at a higher pressure than the first step, which can produce a smoother exterior surface. Furthermore, the first chassis shields the electronic component from the higher pressure of the second step, which reduces the likelihood of damage to the electronic component.

### BACKGROUND

This disclosure relates generally to molding processes and in particular to a multi-step molding process for an electronic device chassis.

Many types of electronic components are fragile and prone to damage. For instance, a flexible printed circuit board can easily be damaged if it is twisted or bent too severely. This can make it difficult for users to properly handle such electronic components and limits the range of applications in which such electronic components can be used.

### SUMMARY

An electronic device is manufactured with multi-step molding process. An electronic component is placed in a first mold, and a first material is injected into the first mold to form a first chassis. The first chassis at least partially surrounds the electronic component to provide support for the electronic component. The first chassis is placed in a second mold, and a second material is injected into the second mold to form a second chassis. The second chassis at least partially surrounds the first chassis.

### BRIEF DESCRIPTION OF THE DRAWINGS

FIG. 1 is a flow chart illustrating a multi-step molding process for manufacturing a chassis for an electronic device, according to one embodiment.

FIG. 2A is a side cutaway view of a flexible printed circuit board (PCB) and a mechanical fastener, according to one embodiment.

FIG. 2B is a perspective view of a flexible PCB and a mechanical fastener, according to one embodiment.

FIG. 2C is a side cutaway view of injecting a first material into a first mold after a flexible PCB and a mechanical fastener have been placed in the first mold, according to one embodiment.

FIG. 2D is a side cutaway view of a first chassis, according to one embodiment.

FIG. 2E is a perspective view of a first chassis, according to one embodiment.

FIG. 2F is a side cutaway view of injecting a second material into a second mold after a first chassis has been placed in the second mold, according to one embodiment.

FIG. 2G is a side cutaway view of a second chassis, according to one embodiment.

FIG. 2H is a perspective view of a second chassis, according to one embodiment.

FIG. 3 is a flow chart illustrating a process for creating an electronic assembly capable of undergoing the multi-step molding process, according to one embodiment.

FIG. 4 illustrates an example of an electronic assembly, according to one embodiment.

The figures depict various embodiments of the present invention for purposes of illustration only. One skilled in the art will readily recognize from the following discussion that alternative embodiments of the structures and methods illustrated herein may be employed without departing from the principles of the invention described herein.

### DETAILED DESCRIPTION

### Overview of the Disclosure

Flexible printed circuit boards (PCBs) have a wide range of uses, but they are also fragile and prone to damage if they are subject to rough handling. One way to protect a flexible PCB from damage is to place the flexible PCB in a mold and perform a single-shot injection molding process to encase the flexible PCB in plastic (or some other material). However, performing a single-shot injection molding process around a flexible PCB has several drawbacks that, in some cases, makes the entire process infeasible. In particular, because injection molding is typically performed at relatively high pressures, a single-shot injection molding process can cause the flexible PCB to rip or tear. This leads to damage to the flexible PCB and can even render the flexible PCB inoperable if one of the tears severs a conductive trace on the flexible PCB. Furthermore, the high pressure of a typical injection molding process can cause the flexible PCB to shift within the mold while the plastic is being injected. This has an adverse impact on manufacturing tolerances and reduces the consistency of the injection molding process, which makes the process less feasible for larger-scale applications.

To address these problems, a chassis for an electronic device is manufactured with a multi-step molding process. The molding process includes at least two separate injection molding steps. During the first injection molding step, an electronic component, such as a flexible PCB, is placed in a first mold, and a first material is injected into the first mold. This results in a first chassis that surrounds part of the electronic component and provides structural support for the electronic component. The first injection molding step can be performed at a lower pressure, which advantageously decreases the likelihood of the flexible PCB becoming damaged or dislodged in the first mold while the first material is being injected.

In the second injection molding step, the first chassis is placed in a second mold, and a second material is injected into the second mold, which results in a second chassis that surrounds part of the first chassis. The second injection molding step can be performed at a higher pressure than the first injection molding step, which advantageously allows the second injection molding step to produce a chassis with an exterior surface that is smoother and has fewer imperfections. Furthermore, the second chassis surrounds part of the first chassis, so the second chassis covers imperfections and roughness that may have been formed into surfaces of the first chassis. In addition, because the first chassis surrounds and provides structural support for the electronic component, the first chassis shields the electronic component from the higher pressure of the second injection molding step, which reduces the likelihood of damage to the electronic component during the second injection molding step.

### Multi-Step Molding Process

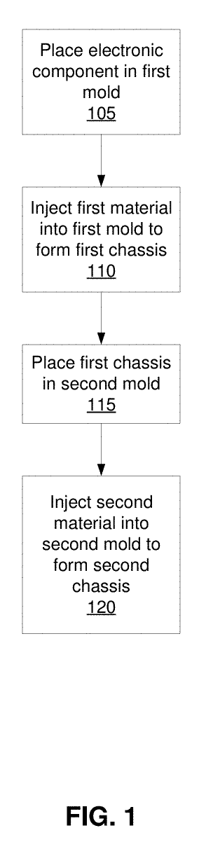

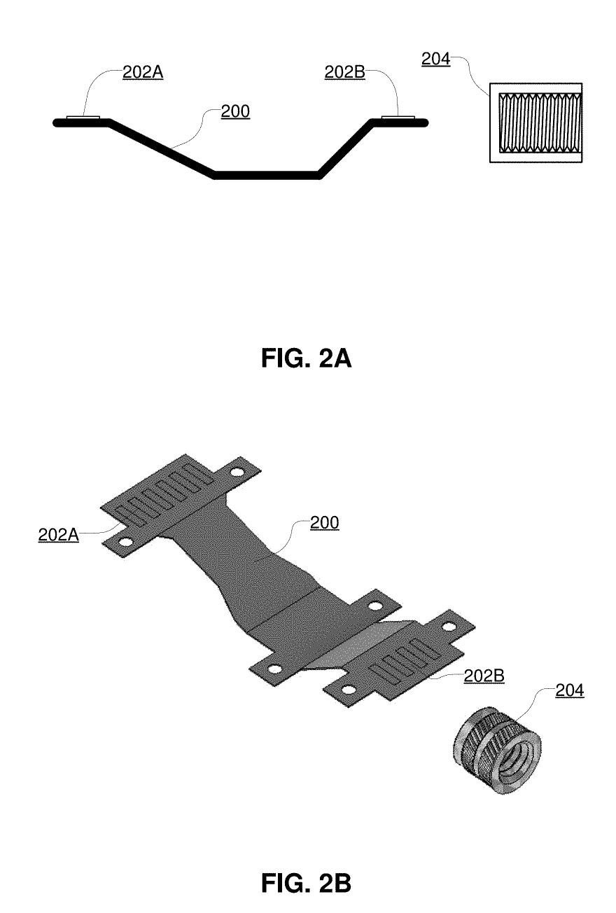

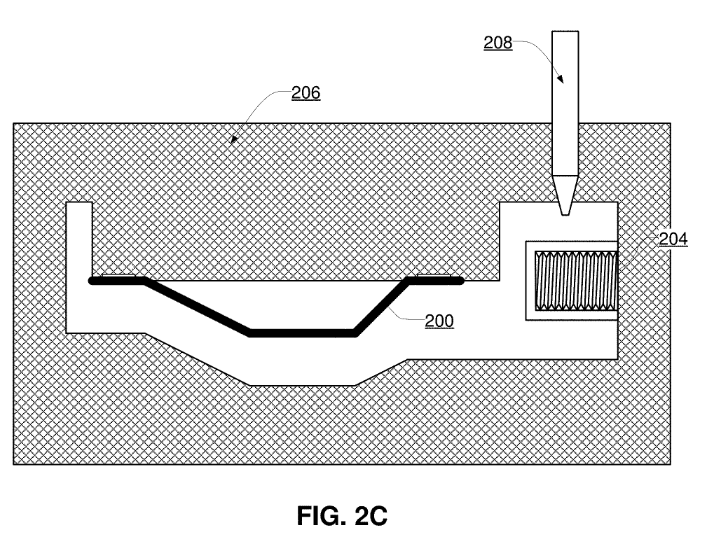

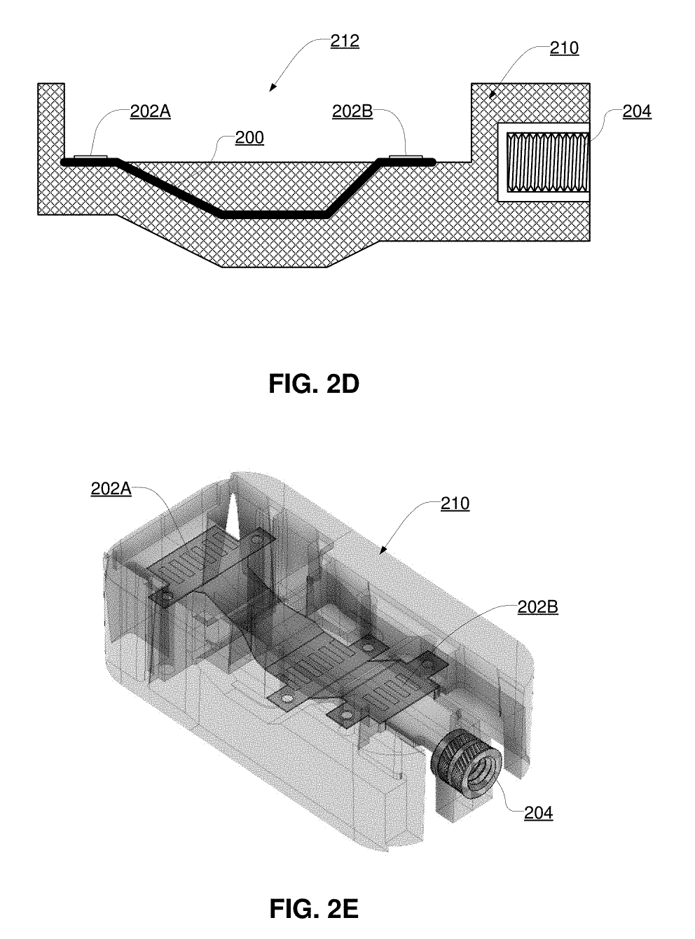

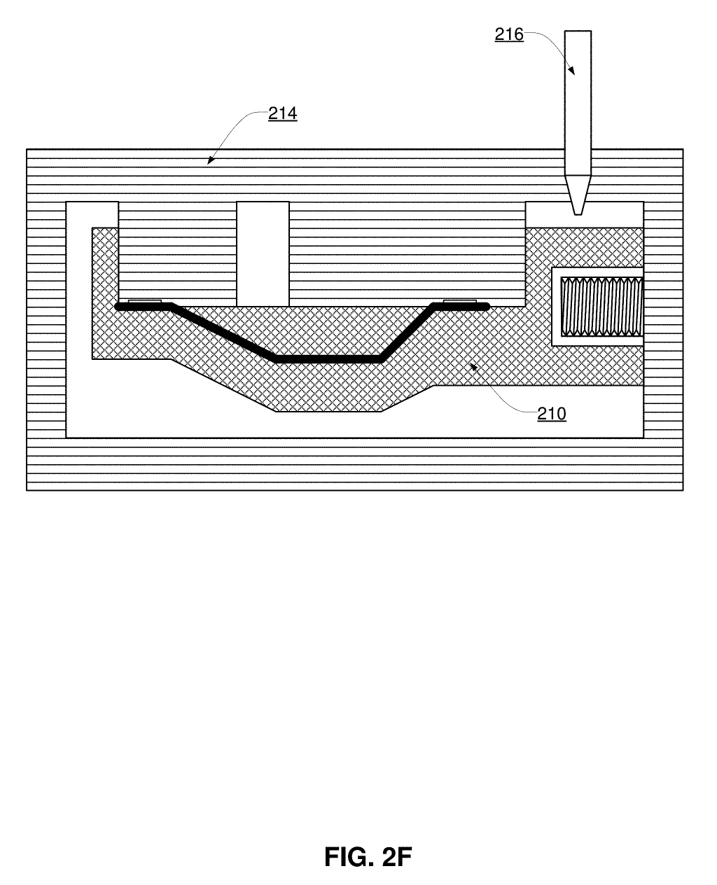

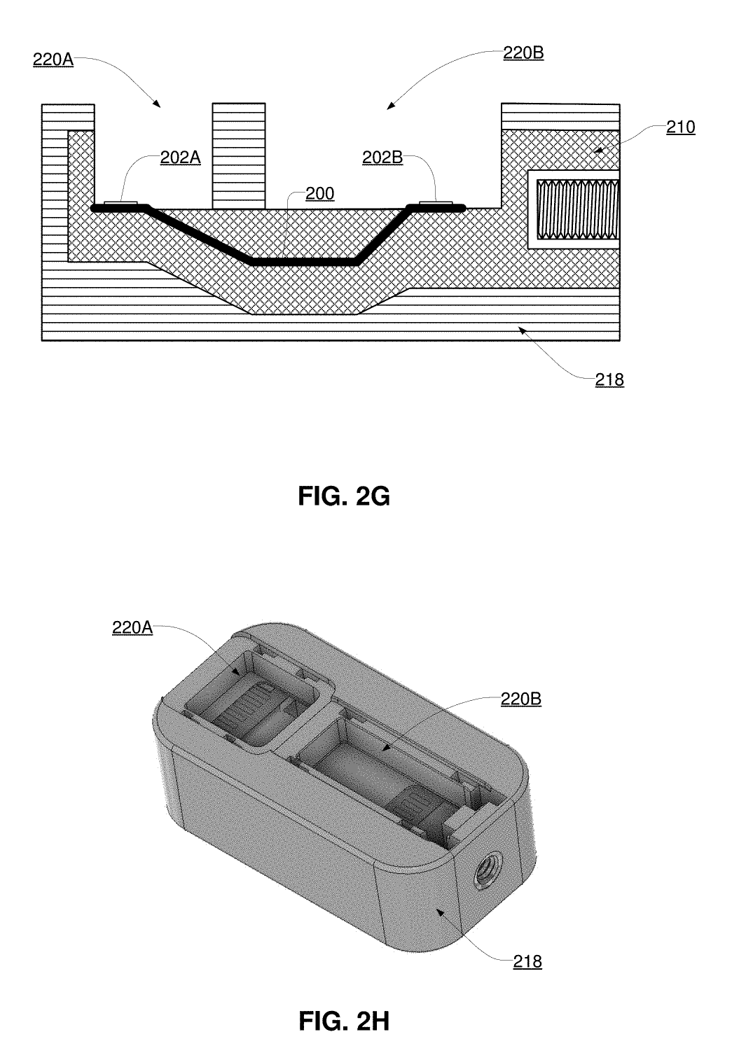

FIG. 1 is a flow chart illustrating a multi-step molding process 100 for manufacturing a chassis for an electronic device, according to one embodiment. FIGS. 2A through 2H illustrate various stages of the multi-step molding process 100, according to one embodiment. For ease of discussion, the process 100 shown in FIG. 1 will be described with reference to the illustrations shown in FIGS. 2A through 2H.

In various embodiments, the two placement steps 105, 115 are performed by a human operator or by a machine (e.g., a robotic arm controlled by a computing device). Meanwhile, the two injecting steps 110, 120 shown in FIG. 1 may be performed with an injection molding machine. In one embodiment, the two injecting steps 110, 120 are performed with separate injection molding machines, and the first chassis is physically moved from one machine to the other. In another embodiment, the two injecting steps 110, 120 are performed with the same injection molding machine, but one or more settings or components of the machine may be changed between the two injecting steps 110, 120 in order to perform the two injecting steps 110, 120 at different pressures, at different temperatures, or with different materials.

The process 100 begins when an electronic component is placed 105 in a first mold. As referred to herein, an electronic component is a component that contains at least one subcomponent capable of conducting electricity. In some embodiments, one or more of the conductive subcomponents are conducive traces. For instance, in the embodiment shown in FIGS. 2A through 2H, the electronic component is a flexible PCB 200 that includes a sheet of flexible material, such as polyethylene terephthalate (PET) or some other flexible thermoplastic, and also includes at least one conductive trace printed on the sheet of flexible material. A flexible PCB may further include additional electronic subcomponents (e.g., integrated circuits, exposed conducting terminals, or electrical connectors) that are electrically coupled to one or more of the conductive traces.

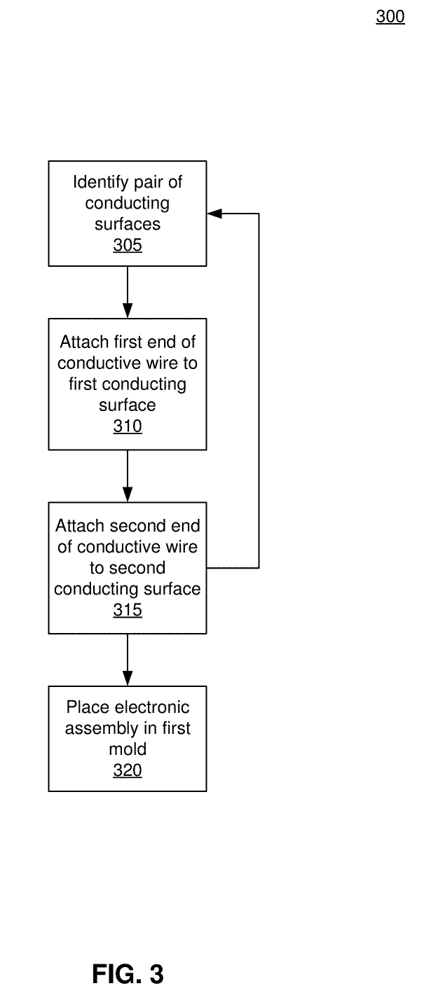

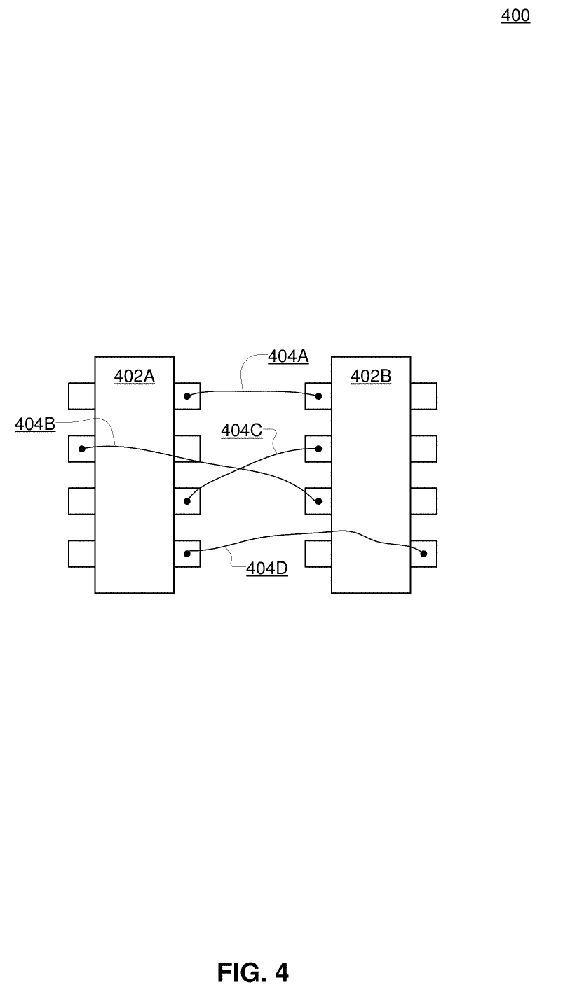

In alternative embodiments, the electronic component is a reinforced flexible PCB or a stamped conductive frame. These embodiments are described in further detail below. In still another alternative embodiment, the multi-step molding process 100 is performed on an electronic assembly rather than an electronic component. An example method for creating an electronic assembly is described below with reference to FIGS. 3 and 4.

An example of a flexible PCB 200 is illustrated in FIGS. 2A and 2B. In the example shown in FIGS. 2A and 2B, the flexible PCB 200 includes two conducting terminals 202A, 202B that are printed on the flexible PCB and can be coupled to a connector of another electronic component to transfer data between the flexible PCB and the other electronic component. Although not shown in FIGS. 2A and 2B, the flexible PCB further includes one or more conductive traces, and may additionally include one more integrated circuits or other electronic components.

In addition to the flexible PCB 200, FIGS. 2A and 2B also illustrate a secondary component 204 that is placed in the first mold along with the flexible PCB. Here, the secondary component a threaded insert configured to receive a screw. In other embodiments, a secondary component can be a different type of mechanical connector, such as a protruding threaded shaft, a clip, or a portion of a latching mechanism. In still other embodiments, a secondary component can be a secondary electrical component, such as an external light-emitting diode (LED) or switch, or some other category of component.

Referring back to FIG. 1, a first material is injected 110 into the first mold to form a first chassis. An example of this injection molding step 110, including a first mold 206 and a nozzle 208 of an injection molding machine, is shown in FIG. 2C, and an example of a first chassis 210 is shown in FIGS. 2D and 2E. In one embodiment, the first material is injected 110 at relatively low pressure. For example, the first material is injected 110 with a one-ton press (i.e., a clamping force of one ton). In other embodiments, the first material is injected 110 with a different clamping force, such as 1.5 tons, 3 tons, 5 tons, or 10 tons.

The first material may also be injected 110 at a relatively low temperature. For example, the first material is injected 110 at a temperature between 120 degrees Celsius and 190 degrees Celsius, or within a temperature range between these two temperatures. In other embodiments, the first material is injected 110 at a temperature or temperature range less than 120 degrees Celsius or greater than 190 degrees Celsius.

In one embodiment, the first material is a type of synthetic resin that has material properties such as a low viscosity, an intermediate temperature stability, and an intermediate impact absorption. For example, the first material is a polyamide, polyurethane, or polystyrene.

This first injecting step 110 forms a first chassis that at least partially surrounds the electronic component. In some embodiments, the first chassis completely surrounds the electronic component by enclosing the electronic component on all sides. In other embodiments, the first chassis includes one or more cutouts that each leave a portion of the electronic component exposed. For instance, the first chassis 210 shown in FIGS. 2D and 2E includes a cutout 212 that leaves two portions of the flexible PCB 200 exposed but encloses other portions of the flexible PCB 200. The two exposed portions correspond to the positions of the two conducting terminals 202A, 202B on the flexible PCB 200, which allows for the conducting terminals 202A, 202B to be coupled to an electronic conductor on another device.

In an embodiment where a secondary component is also placed in the first mold, the first chassis also at least partially surrounds the secondary component. The first chassis may also leave certain portions of the secondary component exposed (e.g., a portion that faces the exterior of the first chassis). For example, the threaded insert 204 shown in FIGS. 2C-2E is exposed on the side that receives the screw, while the other sides of the threaded insert are surrounded by the first chassis. Because the first chassis encloses both the electronic component and the secondary component, the first chassis has the effect of fixing the position of the secondary component relative to the primary component. This can be useful, for example, if the electronic device being manufactured by the molding process 100 is later coupled to a larger apparatus via both a mechanical connector (e.g., to couple to the secondary component) and an electrical connector (e.g., to couple to a conducting terminal or electronical connector that is on an exposed portion of the electronic component). Furthermore, because the first material is injected at a relatively low pressure, the secondary component is less likely to move relative to the electronic component while the first material is being injected.

In an alternative embodiment, the first chassis is formed with a casting process rather than an injection molding process. In this embodiment, the first material is poured into the first mold in a manner. More specifically, the first material is added to the first mold by placing the first material above the first mold and allowing the downward force of gravity to act on the first material so that the first material flows into the first mold. In other words, the first material is added to the first mold without applying any additional force to the first material via an injection molding machine.

The first chassis is placed 115 in a second mold, and a second material is injected 120 into the second mold to form a second chassis. An example of this injection molding step 120, including a second mold 214 and a nozzle 216 of an injection molding machine, is shown in FIG. 2F, and an example of a second chassis 218 is shown in FIGS. 2G and 2H. In some embodiments, the second material is injected 120 at a higher pressure than the first material. In various embodiments, the second material is injected with a clamping force of 20 tons or greater, or a clamping force of between 20 tons and 200 tons. In other embodiments, the second material is also injected 120 at a relatively low pressure. For example, the second material may be injected 120 at same pressure as the first material, or a different pressure that is also relatively low (e.g., a clamping force of less than 20 tons).

The second material may also be injected 120 at a higher temperature than the first material. For example, the second material may be injected 120 at a temperature between 180 degrees Celsius and 350 degrees Celsius, or within a temperature range between these two temperatures. The second material may alternatively be injected 120 at a temperature or temperature range less than 180 degrees Celsius or greater than 350 degrees Celsius.

In one embodiment, the second material is a thermoplastic with material properties such as high strength, high stiffness, high durability, and capable of producing a smooth cosmetic finish. For example, the second material may be acrylonitrile butadiene styrene (ABS) plastic, a polycarbonate/ABS alloy (e.g., a blend of polycarbonate and ABS plastic), nylon, and polypropylene.

The second injecting step 120 forms a second chassis that at least partially surrounds the first chassis. Similar to the first chassis, the second chassis may also include one or more cutouts. The cutouts in the second chassis may be positioned to at least partially align with the cutouts in the first chassis. In an embodiment where the cutouts in the first chassis expose portions of the electronic component, aligning the cutouts in the second chassis with the cutouts in the first chassis advantageously allows access to the exposed portions of the electronic component after the electronic device has been manufactured with this multi-step molding process 100. For example, the example second chassis 218 shown in FIGS. 2G and 2H includes two cutouts 220A, 220B that align with the cutout in the first chassis 210, which allows access to the conducting terminals 202A, 202B on the electronic component 200.

The second injecting step 120 may further form features into one or more exterior surfaces of the second chassis. For example, the second injecting step 120 may form cosmetic features, such as a logo or text, onto an exterior surface of the second chassis. As another example, the second injecting step 120 may form one or mechanical features onto an exterior surface of the second chassis. For example, a slot or a protruding loop capable of being coupled to a mechanical connector (e.g., a clip or hook) may be formed into an exterior surface. Because the second injecting step 120 can performed at a higher pressure and with a stiffer material, exterior features formed during the second injection step 120 may be stronger and more durable than if they were formed at a lower pressure or with a different material, such as the pressure and material used for the first injecting step 110.

In an alternative embodiment, the electronic component is a reinforced flexible PCB. A reinforced PCB includes a flexible PCB and a support structure that at least partially encases the flexible PCB. The support structure may be formed of a bendable metal, such as copper. In this embodiment, the reinforced PCB is placed 105 in the first mold in the rest of the multi-step molding process 100 proceeds in the manner described above. The support structure provides additional support for the flexible PCB, which further reduces the risk of damaging the flexible PCB during the first injecting step 110.

In another alternative embodiment, the electronic component is a conductive frame. A conductive frame (also referred to as a lead frame) is a structure that is manufactured by removing material from a flat sheet of conductive material (e.g., copper or copper alloy) to form one or more conductive leads. The conductive frame may be manufactured via an etching process, a stamping process, or a process that includes a combination of etching and stamping. Similar to the flexible PCB described above, a conductive frame is also relatively fragile and prone to damage because the frame is relatively thin, the conductive leads are relatively narrow, and the frame is typically formed of a relatively soft material, such as copper.

### Creation of Electronic Assembly

FIG. 3 is a flow chart illustrating a process for creating an electronic assembly capable of undergoing the multi-step molding process 300, according to one embodiment. In one embodiment, the first three steps 305 through 315 of the process 300 are performed by controlling a wire bonding machine.

The wire bonding machine identifies 305 a pair of conducting surfaces to be electrically coupled to each other. As referred to herein, a conducting surface is an input or an output terminal for a modular electronic device. A modular electronic device is a subcomponent that includes one or more electronic circuits. In one embodiment, each of the modular electronic devices perform a discrete function (e.g., an adder, multiplexer, etc.). In another embodiment, some of the modular electronic devices perform multiple functions.

The wire bonding machine attaches 310 the first end of a conductive wire to the first conductive surface and attaches 315 the second end of the conductive wire to the second conductive surface. The wire bonding machine can use one or more bonding techniques to attach 310, 315 the ends of the conductive wire to the conductive surfaces. For instance, the wire bonding machine may attach 310, 315 the ends of the conductive wire using a ball bonding process, a wedge bonding process, or a compliant bonding process. In various embodiments, the conductive wire has a thickness of 300 microns or less.

After the wire bonding machine identifies 305 a first pair of conducting surfaces and attaches 310, 315 a conductive wire to the conducting surfaces, the wire bonding machine can identify additional pairs of conducting surfaces and connect them with additional conductive wires. In one embodiment, the wire bonding machine identifies each pair of conducting surfaces by accessing a data file that specifies one or more pairs of conducting surfaces to be connected to each other.

The use of a data file to identify pairs of conducting surfaces to be connected in this manner allows the functionality of the electronic apparatus to be defined in the data file. This is advantageous, for example, because creating a data file is less resource-intensive and time-consuming than designing and manufacturing a custom flexible PCB with the same functionality.

An example of a completed electronic assembly is shown in FIG. 4. In this example, the electronic assembly includes two modular electronic devices 402A, 402B, each with eight conducting surfaces, and four wires 404A through 404D that each connect a pair of conducting surfaces. The electronic assembly can be created, for example, by providing the wire bonding machine with a data file that specifies each of the four pairs of conducting surfaces that are connected by the wires 404A through 404D in FIG. 4.

The completed electronic assembly is placed 320 in the first mold, and the multi-step molding process 100 is performed in the manner described above. Because the conductive wires used to connect the pairs of conducting surfaces can be relatively thin (e.g., 300 microns or less) and fragile, performing the multi-step molding process 100 to manufacture the electronic device can be advantageous, for example, because the lower pressure of the first injecting step can reduce the probability of damaging or displacing the conductive wires.

### Additional Configuration Considerations

The foregoing description of the embodiments of the disclosure has been presented for the purpose of illustration; it is not intended to be exhaustive or to limit the invention to the precise forms disclosed. Persons skilled in the relevant art can appreciate that many modifications and variations are possible in light of the above disclosure.

The language used in the specification has been principally selected for readability and instructional purposes, and it may not have been selected to delineate or circumscribe the inventive subject matter. It is therefore intended that the scope of the invention be limited not by this detailed description, but rather by any claims that issue on an application based hereon. Accordingly, the disclosure of the embodiments of the invention is intended to be illustrative, but not limiting, of the scope of the invention, which is set forth in the following claims.

What is claimed is:

1. A method comprising:
placing an electronic component in a first mold, the electronic component including at least one conductive trace;
injecting a first material into the first mold to form a first chassis responsive to placing the electronic component in the first mode, the first chassis at least partially surrounding the electronic component to provide support for the electronic component;
placing the first chassis in a second mold responsive to injecting the first material into the first mold; and
injecting a second material into the second mold to form a second chassis responsive to placing the first chassis in the second mold, the second chassis at least partially surrounding the first chassis.

2. The method of claim 1, wherein the first material and the second material are the same material.

3. The method of claim 1, wherein the first material is selected from a group of materials consisting of polyamide, polyurethane, and polystyrene.

4. The method of claim 1, wherein the second material is selected from a group of materials consisting of acrylonitrile butadiene styrene (ABS) plastic, polycarbonate/ABS alloy, nylon, and polypropylene.

5. The method of claim 1, wherein the first material is injected at a pressure lower than a pressure at which the second material is injected.

6. The method of claim 1, wherein the first material is injected at a temperature lower than a temperature at which the second material is injected.

7. The method of claim 1, further comprising:
before injecting the first material into the first mold, placing a secondary component in the first mold.

8. The method of claim 7, wherein the first chassis at least partially surrounds the secondary component to provide support for the secondary component.

9. The method of claim 8, wherein the secondary component is a mechanical connector.

10. The method of claim 1, wherein the first chassis includes a first cutout, and the second chassis includes a second cutout, the first cutout and the second cutout aligning to expose a portion of the electronic component.

11. The method of claim 10, wherein the exposed portion of the electronic component contains a conducting terminal for transferring data between the electronic component and another electronic component.

12. The method of claim 1, wherein the electronic component is a flexible printed circuit board (PCB), the flexible PCB comprising a sheet of flexible material and at least one conductive trace printed on the sheet of flexible material.

13. The method of claim 1, wherein the electronic component is a reinforced flexible printed circuit board (PCB), the reinforced flexible PCB comprising a flexible PCB and a support structure at least partially encasing the flexible PCB, the flexible PCB comprising a sheet of flexible material and at least one conductive trace printed on the sheet of flexible material.

14. The method of claim 1, wherein the electronic component is a stamped lead frame.

15. An electronic device manufactured by a process comprising:
placing an electronic component in a first mold, the electronic component including at least one conductive trace;
injecting a first material into the first mold to form a first chassis responsive to placing the electronic component in the first mode, the first chassis at least partially surrounding the electronic component to provide support for the electronic component;
placing the first chassis in a second mold responsive to injecting the first material into the first mold; and
injecting a second material into the second mold to form a second chassis responsive to placing the first chassis in the second mold, the second chassis at least partially surrounding the first chassis.

16. The electronic device of claim 15, wherein the first chassis includes a first cutout, and the second chassis includes a second cutout, the first cutout and the second cutout aligning to expose a portion of the electronic component.

17. The electronic device of claim 16, wherein the exposed portion of the electronic component contains a conducting terminal for transferring data between the electronic component and another electronic component.

18. A method comprising:
connecting a first connecting surface of a first modular circuit to a second connecting surface of a second modular circuit using a wire bonding machine to obtain an electronic assembly;
placing the electronic assembly in a first mold;
injecting a first material into the first mold to form a first chassis responsive to placing the electronic assembly in the first mold, the first chassis at least partially surrounding the assembly to provide support for the electronic assembly;
placing the first chassis in a second mold responsive to injecting the first material into the first mold; and
injecting a second material into the second mold to form a second chassis responsive to placing the first chassis in the second mold, the second chassis at least partially surrounding the first chassis.

19. The method of claim 18, wherein connecting the first connecting surface to the second connecting surface comprises attaching a first end of a conductive wire to the first connecting surface and attaching a second end of the conductive wire to the second connecting surface.

20. The method of claim 19, wherein the conductive wire has a diameter of less than 300 microns.
